(19) United States
(12) Patent Application Publication
(10) Pub. No.: US 2026/0197959 A1
(43) Pub. Date: Jul. 9, 2026

(54) AUTOMATION FIELD DEVICE

(71) Applicant: Endress+Hauser SE+Co. KG, Maulburg (DE)

(72) Inventors: Armin Gerland, Häg-Ehrsberg (DE); Jürgen Tanner, Kandern (DE); Rouven Kummle, Wehr (DE); Alexander Meier, Fischingen (DE)

(21) Appl. No.: 19/132,057

(22) PCT Filed: Nov. 3, 2023
(86) PCT No.: PCT/EP2023/080640

§ 371 Date: May 22, 2025

(30) Foreign Application Priority Data
Nov. 30, 2022 (DE) 10 2022 131 777.3

(51) Int. Cl. H05K 7/14

(52) U.S. Cl. CPC H05K 7/1462

(57) ABSTRACT

The present disclosure relates to an automation field device with a housing for accommodating the field device electronics. The housing has a substantially cup-shaped housing cover, which is provided in a cup surface with a recess for a viewing window, where a viewing window insert made of a transparent material rests on an inner side of the housing cover at the edge of the recess, wherein a resilient molded plastic part is provided for receiving and holding the viewing window insert, which is pressed into the free space between the inside of the housing cover and the edge of the viewing window insert in such a way that the molded plastic part, on the one hand, substantially fills the free space and, on the other hand, also holds the viewing window insert permanently in the housing cover without any further fastening means.

The invention relates to an automation field device with a housing for accommodating field device electronics of the field device.

In automation technology, especially in process automation technology, in many instances field devices serving to capture and/or influence process variables are used in what are known as automation systems. Sensors, for example fill-level measuring devices, flow meters, pressure and temperature measuring devices, pH-redox potential measuring devices, conductivity measuring devices etc., which capture the corresponding process variables of fill level, flow, pressure, temperature, pH level, or conductivity serve for the recording of process variables. Actuators, for example drives, aggregates, valves, pumps, via which the flow rate of a fluid in a pipeline segment or the fill level in a container can be altered, serve to influence process variables.

Field devices, in general, refer to all devices which are used in a process-oriented manner and which supply or process process-relevant information, that is, substantially process measured values or process control values.

The Endress+Hauser Group develops, produces and distributes a large variety of such field devices.

Such field devices are often designed to consist of a housing base and a housing cover. Both parts are substantially cup-shaped and arranged relative to one another in such a way that their cup openings are opposite one another so that the housing part is closed by the housing cover. The housing cover typically has a recess in its cup-shaped bottom surface for a transparent viewing window insert, for example made of a plastic or a glass.

In order to realize a resilient connection between the transparent viewing window insert and the housing cover, the viewing window insert is connected to the housing cover using a cured and thus non-resilient potting compound. The potting compound is located radially between the outer diameter of the viewing window insert and the inner diameter of the housing cover. For this purpose, the metal cover is currently moistened on the inner side with an adhesion promoter. Furthermore, the viewing window insert is also moistened with an adhesion promoter on the outer side or on the outer diameter. A liquid/viscous potting compound is then poured into the gap between the viewing window insert and the housing cover. This potting compound, which is often based on silicone today, then cures and thereby creates the connection between the viewing window insert and the housing cover. The potting compound is under tensile stress so that without further measures, no pressure-bearing connection can be realized between the viewing window insert and the housing cover. For this reason, in addition to the potting compound, a substantially cylindrical retaining ring or snap ring with an oversize is inserted into a gap introduced in the housing cover behind the viewing window insert, as seen from the outside in the axial direction. Compressive stresses are exerted on the viewing window insert via the retaining or snap ring, which make a pressure-tight connection possible between the viewing window insert and the housing cover.

The disadvantage here in particular is that the production process with regard to the introduction of the potting compound (cleaning, applying adhesion promoter, dosing, checking the viscosity during filling, curing times and temperatures) is highly complex and thus cost-intensive. Additional manufacturing costs are subsequently also incurred due to the retaining ring or snap ring required in addition to the potting compound.

The invention is based on the object of demonstrating a way to introduce a viewing window insert into a housing cover for an automation field device as cost-effectively as possible.

The object is achieved according to the invention by the automation field device with a housing for accommodating field device electronics of the field device according to claim 1.

The automation field device according to the invention with a housing for accommodating field device electronics provides that the housing has a substantially cup-shaped housing cover which is provided in a cup surface with a recess for a viewing window, wherein a viewing window insert made of a transparent material rests on an inner side of the housing cover at the edge of the recess, wherein a resilient molded plastic part is provided for receiving and holding the viewing window insert which is pressed in the free space between the inner side of the housing cover and the edge of the viewing window insert in such a way that the molded plastic part, on the one hand, substantially fills the free space and, on the other hand, also holds the viewing window insert permanently in the housing cover without any further fastening means.

According to the invention, a resilient molded plastic part is proposed for receiving and holding the viewing window insert which rests on an inner side of the housing cover at the edge of the recess. Here, resting is also to be understood as only partial resting or, if applicable, a slight spacing, which is brought about by the effect caused by the resilient molded plastic part, which will be described in more detail below.

The resilient molded plastic part is radially compressed by axial insertion between the outer diameter of the viewing window insert and the inner diameter of the housing cover. The forces acting in the radial direction that are exerted by the resilient molded plastic part keep the viewing window insert in position and ensure a pressure-tight connection. Due to the acting forces, after the insertion of the resilient molded plastic part, it may happen that the viewing window insert may no longer rest completely on the inner side of the housing cover at the edge of the recess.

The resilient molded plastic part can, for example, be designed as an elastomer molded plastic part. In particular, it can be designed as a ring-shaped elastomer molded plastic part. For example, the resilient molded plastic part can be made of HNBR (which stands for hydrogenated acrylonitrile-butadiene rubber). This material has the advantage of being chemically resistant to oils and greases. Furthermore, this material manifests good cold and high temperature behavior and can be used from −40° C. to 140° C. In addition, the mechanical strength of the material is good, as well as its damping and compression set.

An advantageous configuration of the field device according to the invention provides that the housing cover on the inner side, in the region where the molded plastic part is pressed in, and/or an edge of the viewing window insert, comprises an outwardly or inwardly projecting bulge.

A further advantageous configuration of the field device according to the invention provides that the viewing window insert and/or housing cover is/are designed in such a way that the pressed-in resilient molded plastic part has a, in particular funnel-shaped, widening at at least one, preferably at both axial ends.

According to a further advantageous configuration, the field device is obtainable in that the resilient molded plastic part is pressed into the free space in such a way that the initially non-compressed molded plastic part with a lateral extension of X′ after pressing in has a lateral extension X less than 0.85*X′ (X<0.85*X′), preferably less than 0.7*X′ (X<0.7*X′), particularly preferably less than 0.55*X′ (X<0.55*X′), where X′ stands for a lateral extension of the molded plastic part in the non-compressed state and X for a lateral extension of the molded plastic part in the compressed state.

According to a further advantageous configuration, the field device is obtainable in that the resilient molded plastic part is pressed into the free space in such a way that the initially non-compressed molded plastic part with an axial extension of Y′ after pressing in has an axial extension Y greater than 1.25*Y (Y>1.25*Y′), preferably greater than 1.5*Y (Y>1.5*Y′), particularly preferably greater than 1.75*Y (Y>1.75*Y′), where Y′ stands for an axial extension of the molded plastic part in the non-compressed state and Y for an axial extension of the molded plastic part in the compressed state.

The invention is explained in more detail on the basis of the following drawings. in which:

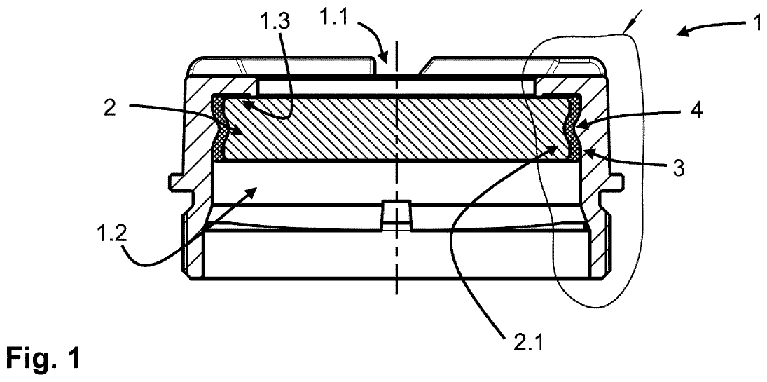

FIG. 1: shows a longitudinal section through a housing cover according to a first embodiment, and

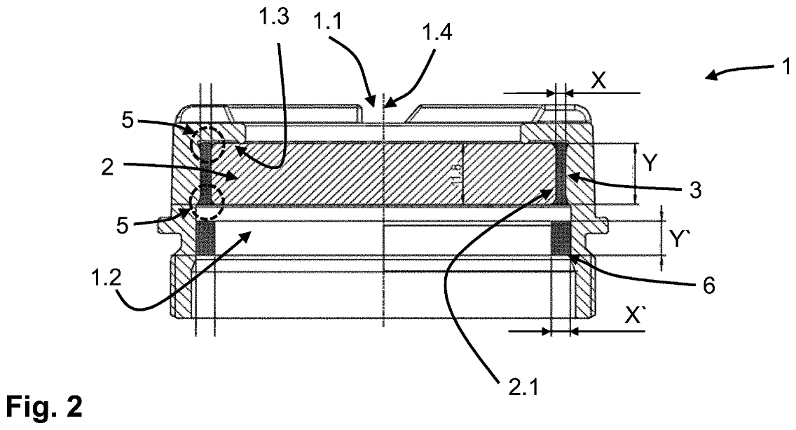

FIG. 2: shows a longitudinal section through a housing cover according to a second embodiment.

In the figures, the same parts are identified with the same reference signs.

FIG. 1 shows a longitudinal section through a housing cover 1 of an automation field device. The housing cover 1 has a substantially cup-shaped configuration and is thus rotationally symmetrical to an axial axis 1.4. A viewing window insert 2 rests on an edge of a recess 2.1 in the cup-shaped bottom surface, which is facing upwards in FIG. 1. The viewing window insert 2, which can be pressure-stable, preferably made of glass and/or plastic, is held by a resilient molded plastic part 3 and sealed thereby circumferentially between an inner side of the housing cover 1.2 and the surrounding edge of the viewing window insert 2.1.

The resilient molded plastic part 3 can, for example, be designed as an elastomer molded plastic part 3. Additionally or alternatively, it can be designed as a ring-shaped molded plastic part. For example, the resilient molded plastic part can be made of HNBR (which stands for hydrogenated acrylonitrile-butadiene rubber). This material has the advantage of being chemically resistant to oils and greases. Furthermore, this material manifests good cold and high temperature behavior and can be used from −40° C. to 140° C. In addition, the mechanical strength of the material is good, as well as the damping and compression set.

After the compression of the elastomer molded plastic part 3 in the installed state, the enclosing contour has at least one opposing cylindrical surface on the glass pane and the metal housing.

Additionally or alternatively as shown in FIG. 1, in the region of the side walls of the viewing window insert 1, the resilient molded plastic part 3 and/or the edge of the viewing window insert 2.1 can have an outwardly and/or inwardly projecting bulge 4, in order to thereby achieve increased stability, in particular with regard to possible slipping or shifting of the glass pane or the ring.

The resilient molded plastic part 3 is designed in such a way that it completely fills the free space between an inner side of the housing cover 1.2 and the edge of the viewing window insert 2.1 and substantially holds the viewing window insert 2 in the inserted position without the need for any further fastening means, such as a retaining or snap ring. For this purpose, the resilient molded plastic part 3 is compressed radially so that the molded plastic part 3 generates forces acting in the radial direction in order to hold the viewing window insert 2 in position and to create a firm connection. This can be realized, for example, in such a way that the resilient molded plastic part 3, in the non-installed state, has a greater wall thickness than the gap to be filled in order to be able to deform resiliently in the installed state so that in the installed state, it takes up the wall thickness of the gap and is stretched in width.

In this regard, FIG. 2 shows by way of example, in the lower part of the housing cover 1, a molded plastic part 6 that is not yet compressed with a lateral extension of X′ and an axial extension of Y′, and in the upper part of the housing cover, a compressed molded plastic part 3 with a lateral extension of X and an axial extension of Y.

The compression can be realized, for example, in that the resilient molded plastic part 3 is introduced into the free space in such a way that the initially non-compressed molded plastic part 3 with a lateral extension of X′ after pressing in has a lateral extension of less than 0.85*X′, i.e. the following applies: X<0.85*X′, preferably less than 0.7*X′, i.e. the following applies: X<0.7*X′, particularly preferably less than 0.55*X, i.e. the following applies: X<0.55*X′.

Additionally or alternatively, the resilient molded plastic part 3 can be pressed in the free space in the axial direction in such a way that the initially non-compressed molded plastic part with an axial extension of Y′ after pressing in has an axial extension Y greater than 1.25*Y, i.e. the following applies: Y>1.25*Y′, preferably greater than 1.5*Y, i.e. the following applies: Y>1.5*Y′, particularly preferably greater than 1.75*Y, i.e. the following applies: Y>1.75*Y′.

In addition, as shown in FIG. 2, the viewing window insert 2 and/or housing cover 1 can be designed in such a way that the pressed-in resilient molded plastic part 3 has a, in particular funnel-shaped, widening or projection 5 at at least one, preferably at both axial ends. This projection ensures that the resilient molded plastic part 3 and the viewing window insert 2 are held in axial position relative to the housing cover 1.

### LIST OF REFERENCE SIGNS

1 Housing cover
1.1 Recess for a viewing window
1.2 Inner side of the housing cover
1.3 Edge of the recess
1.4 Axial axis
2 Viewing window insert
2.1 Edge of the viewing window insert
3 Resilient molded plastic part
4 Bulge
5 In particular, funnel-shaped widening
6 Resilient molded plastic part, not yet compressed
X′ Lateral extension of the molded plastic part in the non-compressed state
X Lateral extension of the molded plastic part in the compressed state
Y Axial extension of the molded plastic part in the non-compressed state
Y Lateral extension of the molded plastic part in the compressed state

1-5. (canceled)

6. An automation field device, including:
a housing for accommodating electronics of the field device, wherein the housing has a substantially cup-shaped housing cover which is provided in a cup surface with a recess for a viewing window;
a viewing window insert made of a transparent material resting on an inner side of the housing cover at the edge of the recess;
a resilient molded plastic part for receiving and holding the viewing window insert, which is pressed into the free space between the inside of the housing cover and the edge of the viewing window insert in such a way that the molded plastic part, on the one hand, substantially fills the free space and, on the other hand, also holds the viewing window insert permanently in the housing cover without any further fastening.

7. The field device according to claim 5, wherein the housing cover comprises an outwardly and/or inwardly projecting bulge on the inner side, in the region where the molded plastic part is pressed in or an edge of the viewing window insert.

8. The automation field device according to claim 5, wherein the viewing window insert or housing cover is designed in such a way that the pressed-in resilient molded plastic part has a widening at at least one axial end.

9. The automation field device according to claim 5, obtainable in that the resilient molded plastic part is pressed into the free space in such a way that the initially non-compressed molded plastic part with a lateral extension of X′ after pressing in has a lateral extension X less than 0.85* X.

10. The automation field device according to claim 4, obtainable in that the resilient molded plastic part is pressed into the free space in such a way that the initially non-compressed molded plastic part with an axial extension of Y′ after pressing in has an axial extension Y greater than 1.25*Y.
